(19) United States
(12) Patent Application Publication
(10) Pub. No.: US 2020/0194328 A1
(43) Pub. Date: Jun. 18, 2020

(54) DEVICE PACKAGES AND METHOD OF MANUFACTURING THE SAME

(71) Applicant: Advanced Semiconductor Engineering, Inc., Kaohsiung (TW)

(72) Inventors: Cheng-Ling HUANG, Kaohsiung (TW); Ying-Chung CHEN, Kaohsiung (TW); Lu-Ming LAI, Kaohsiung (TW)

(73) Assignee: Advanced Semiconductor Engineering, Inc., Kaohsiung (TW)

(21) Appl. No.: 16/218,422

(22) Filed: Dec. 12, 2018

(51) Int. Cl. H01L 23/31; H01L 23/498; H01L 23/00; H01L 21/56

(52) U.S. Cl. CPC H01L 23/3171; H01L 23/49838; H01L 2924/16151; H01L 21/56; H01L 24/17

(57) ABSTRACT

A device package includes a first carrier, a lid and a chip. The first carrier includes a substrate having a first surface and a second surface opposite to the first surface. The substrate defines a through-hole extended from the first surface to the second surface. The through-hole includes a first opening proximal to the first surface, and a second opening proximal to the second surface. The first barrier dam is disposed on the first surface and surrounds the first opening of the through-hole. The second barrier dam is disposed on the second surface and surrounds the second opening of the through-hole. The lid is disposed on the first surface. The lid and the first carrier define a chamber. The chip is disposed on the first surface and in the chamber.

### BACKGROUND

### 1. Technical Field

The present disclosure relates to a device package. In particular, the present disclosure relates to a device package having a lid and a method of manufacturing the same.

### 2. Description of the Related Art

A semiconductor device package may use a carrier and a substrate which together define a chamber. The substrate may define a through-hole for eliminating the pop-corn effects during the heating operation. The larger aperture of the opening of the through-hole may result in saw dust flowing into the chamber. However, it is difficult to form a smaller aperture of the opening of the through-hole.

### SUMMARY

In an aspect, according to some embodiments, a device package comprises a first carrier, a lid and a chip. The first carrier comprises a substrate having a first surface and a second surface opposite to the first surface. The substrate defines a through-hole extended from the first surface to the second surface. The through-hole includes a first opening proximal to the first surface, and a second opening proximal to the second surface. The first barrier dam is disposed on the first surface and surrounds the first opening of the through-hole. The second barrier dam is disposed on the second surface and surrounds the second opening of the through-hole. The lid is disposed on the first surface. The lid and the first carrier define a chamber. The chip is disposed on the first surface and in the chamber.

In an aspect, according to some embodiments, a device package comprises a first carrier, a bottom barrier dam, a lid and a chip. The first carrier comprises a first surface and a second surface opposite to the first surface. The first carrier defines a through-hole extended from the first surface to the second surface. The through-hole has a first opening adjacent to the first surface and a second opening adjacent to the second surface. The bottom barrier dam is disposed on the second surface and surrounds the bottom opening of the through-hole. The bottom barrier dam has an opening, and a dimension of the opening of the bottom barrier dam ranges from about 20 μm to about 50 μm. The lid is disposed on the first surface. The lid and the first carrier define a chamber. The chip is disposed on the first surface and in the chamber.

In an aspect, according to some embodiments, an electronic device comprises a first carrier and a device package. The first carrier has a top surface. The device package is disposed on the top surface of the first carrier. The device package comprises a second carrier having a first surface and a second surface opposite to the first surface and facing the top surface of the first carrier; a chip disposed on the first surface; and a connection element connecting the top surface of the first carrier to the second surface of the second carrier. A gap between the top surface of the first carrier and the second surface of the second carrier is less than about 10 μm.

### BRIEF DESCRIPTION OF THE DRAWINGS

FIG. 1 is a cross-sectional view of a device package in accordance with an embodiment of the present disclosure.

FIG. 2 is a cross-sectional view of a device package in accordance with an embodiment of the present disclosure.

FIG. 3A is a cross-sectional view of a portion of a carrier in accordance with an embodiment of the present disclosure.

FIG. 3B is a cross-sectional view of a device package in accordance with an embodiment of the present disclosure.

FIG. 4 is a cross-sectional view of a portion of a carrier in accordance with an embodiment of the present disclosure.

FIG. 5 is a cross-sectional view of a device package in accordance with an embodiment of the present disclosure.

FIG. 6A, FIG. 6B, FIG. 6C, and FIG. 6D illustrate a method of manufacturing a device package in accordance with an embodiment of the present disclosure.

FIG. 7A, FIG. 7B, FIG. 7C, FIG. 7D, and FIG. 7E illustrate a method of manufacturing a device package in accordance with an embodiment of the present disclosure.

FIG. 8A, FIG. 8B, FIG. 8C, FIG. 8D, FIG. 8E, FIG. 8F, FIG. 8G, and FIG. 8H illustrate a method of manufacturing a portion of a carrier in accordance with an embodiment of the present disclosure.

FIG. 9A, FIG. 9B, FIG. 9C, and FIG. 9D illustrate a method of manufacturing a portion of a carrier in accordance with an embodiment of the present disclosure.

FIG. 10A and FIG. 10B are cross-sectional views of a portion of a carrier in accordance with an embodiment of the present disclosure.

Common reference numerals are used throughout the drawings and the detailed description to indicate the same or similar elements. Embodiments of the present disclosure will be more apparent from the following detailed description taken in conjunction with the accompanying drawings.

### DETAILED DESCRIPTION

Described in this disclosure are techniques for improving the quality of attachment of a lid of a semiconductor device package. Moreover, the techniques may avoid the lid being detached from the substrate due to a pop-corn effect resulting from the thermal cycles.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated by such arrangement.

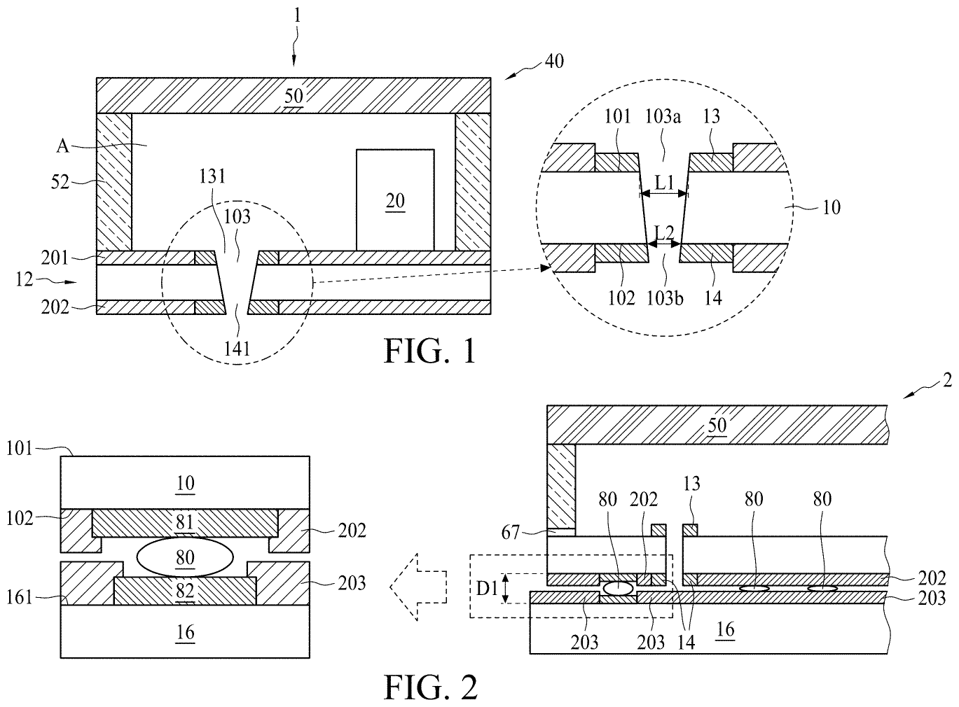

FIG. 1 is a cross-sectional view of a device package 1 in accordance with an embodiment of the present disclosure. The device package 1 includes a carrier 12, a lid 40 and a chip 20. The carrier 12 includes a substrate 10, a passivation layer 201, a passivation layer 202, a barrier dam 13, and a barrier dam 14. The substrate 10 has a surface (e.g., an upper surface) 101 and another surface (e.g., a lower surface) 102 opposite to the surface 101. In some embodiments, the material of the substrate 10 may include a semiconductor, glass, a polymer (e.g., polypropylene (PP)), a resin (e.g., Bismaleimide-triazine (BT) resin or a glass-reinforced epoxy resin like FR-4 resin), a copper clad laminate (CCL) substrate or another suitable material to support components thereon. Although not illustrated in FIG. 1, it is contemplated that the substrate 10 may include one or more redistribution structures, which may include conductive traces, vias, pads or the like.

In some embodiments, the chip 20 comprises an optical chip such as an optical sensor chip, a light emitting chip or the like. In some embodiments, the lid 40 may include a transparent lid, which allows light to pass through. The lid 40 may comprise a cover 50 and sidewalls 52. The cover 50 and the sidewalls 52 may be a monolithic structure formed integrally, or two or more pieces formed individually and connected to each other. In some embodiments, the cover 50 may include a glass layer, and the sidewalls 52 may comprise organic material, such as thermoplastic plastic. By way of example, the sidewalls 52 may comprise Liquid Crystal Polymer (LCP). In some embodiments, the device package 1 may include an electronic device package, a semiconductor device package, an optoelectronic device package or a MEMS device package.

The substrate 10 defines a through-hole 103 extended from the surface 101 to the surface 102. The through-hole 103 includes an opening 103a proximal to the surface 101 and an opening 103b proximal to the surface 102. In FIG. 1, one device package 1 is illustrated by example.

The barrier dam 13 is disposed on the surface 101 and surrounds the opening 103a of the through-hole 103. The barrier dam 14 is disposed on the surface 102 and surrounds the opening 103b of the through-hole 103. The lid 40 is disposed on the surface 101. The lid 40 and the carrier 12 together define a chamber A. The chip 20 is disposed on the surface 101 and in the chamber A. The opening 103a of the through-hole 103 has a first aperture L1, and the opening 103b of the through-hole 103 has a second aperture L2. In some embodiments, the first aperture L1 is larger than the second aperture L2. In some embodiments, the through-hole 103 may have a continuous inclined profile in which the variation of apertures of the through-hole 103 decreases from the surface 101 to the surface 102 substantially continuous. Alternatively, the variation of apertures of the through-hole 103 may decrease discontinuously. In some embodiments, the second aperture of the opening 103b ranges from about 20 μm to about 50 μm.

The barrier dam 13 has an opening 131 having a first dimension. The first dimension of the opening 131 of the barrier dam 13 is, but not limited to, substantially the same as the first aperture of the opening 103a. The barrier dam 14 has an opening 141 having a second dimension. The second dimension of the opening 141 of the barrier dam 14 is substantially the same as the second aperture of the opening 103b. In some embodiments, a second dimension of the opening 141 of the bottom barrier dam 14 is, but not limited to, substantially the same as or smaller than the second aperture of the opening 103b. The second dimension of the opening 141 ranges from about 20 μm to about 50 μm.

In some embodiments, the barrier dam 13 and the barrier dam 14 comprise conductive materials. By way of examples, the barrier dam 13 and the barrier dam 14 may individually comprise thermal conductive materials such as metals or alloys. Examples of the material(s) of the barrier dam 13 and the barrier dam 14 may include Cooper-Palladium-Gold (Cu—Pd—Au), Cu, nickel (Ni), Pd, Au or the combination thereof, conductive gel/glue, or other suitable materials. In some embodiments, the carrier 12 comprises a passivation layer 201 on the surface 101 of the substrate 10 and partially covering the barrier dam 13. In some embodiments, the carrier 12 comprises a passivation layer 202 on the surface 102 of the substrate 10 and partially covering the barrier dam 14.

The barrier dam 13 is disposed on the surface 101 and surrounds the opening 103a of the through-hole 103. The barrier dam 13 may help to maintain the first aperture L1 of the opening 103a, and to alleviate the blocking of thermal carbonization of the substrate 10 due to the heat of drilling operation such as the laser drilling operation. The second aperture L2 of the opening 103b of the through-hole 103 may be about 20 μm for preventing saw dust from entering the chamber A during the manufacturing operations. The first aperture L1 of the opening 103a of the through-hole 103 is larger than the second aperture L2 of the opening 103b of the through-hole 103. The barrier dam 14 is disposed on the surface 102 and surrounds the opening 103b of the through-hole 103. The barrier dam 14 may help to maintain the second aperture L2 of the opening 103a, and to prevent saw dust from entering the chamber A during the manufacturing operations. In some embodiments, the passivation layers 201 and 202 may individually include solder mask layers or other suitable insulative or dielectric materials. The passivation layer 201 on the surface 101 and the passivation layer 202 on the surface 102 may protect the barrier dam 13 and the barrier dam 14.

The device packages depicted in the following drawings are similar in some ways to the device package 1 of FIG. 1, and some same-numbered components are not described again with respect to the following drawings.

FIG. 2 is a cross-sectional view of a device package 2 in accordance with an embodiment of the present disclosure. The structure of the device package 1 of FIG. 2 is similar to the structure of the device package 1 of FIG. 1 except for the passivation layer 201. The device package 2 comprises a device package 1, a carrier 16, pads 82 and connection elements 80. The carrier 16 has a top surface 161. The device package 1 is disposed on the top surface 161 of the carrier 16. In some embodiments, the material of the carrier 16 may include a semiconductor material, glass, a polymer (e.g., PP), a resin (e.g., BT resin or a glass-reinforced epoxy resin like FR-4 resin), a CCL substrate or another suitable material to support components thereon.

The device package 1 comprises a carrier 12, a passivation layer 202, a lid 40, a chip 20 and pads 81. The carrier 12 has a substrate 10. The substrate 10 has a surface 101 and a surface 102 opposite to the surface 101. The carrier 16 has a surface 161, a passivation layer 203 and pads 82. In some embodiments, the material of the pads 81 and 82 may individually include metal or alloy such as Cu—Pd—Au, Cu, Ni, Pd, Au or the combination thereof, or other suitable materials.

The surface 102 faces the surface 161 of the carrier 16. The chip 20 is disposed on the surface 101. A connection element 80 connects the top surface 161 of the carrier 16 to the surface 102 of the carrier 12. In some embodiments, the connection element 80 may include a conductive bump, a conductive ball or a conductive pillar such as a solder bump, a solder ball or a metal pillar. In some embodiments, the material of the connection element 80 may include tin (Sn). A gap D1 between the surface 161 of the carrier 16 and the surface 102 of the substrate 10 is substantially equal to or less than about 10

The carrier 12 is electrically connected to the carrier 16 through the connection element 80. A smaller distance between the carrier 16 and the carrier 12 being less than 10 μm may prevent the saw dust from entering the chamber A during the manufacturing operations, and thus yield and reliability of the device package 2 can be improved. The lid 40 is attached to the surface 101 of the substrate 10 through an adhesive gel/glue 67 or soldering. The adhesive gel/glue 67 may be cured by a heating operation and/or optical irradiation operation during the manufacturing process of the device package 1.

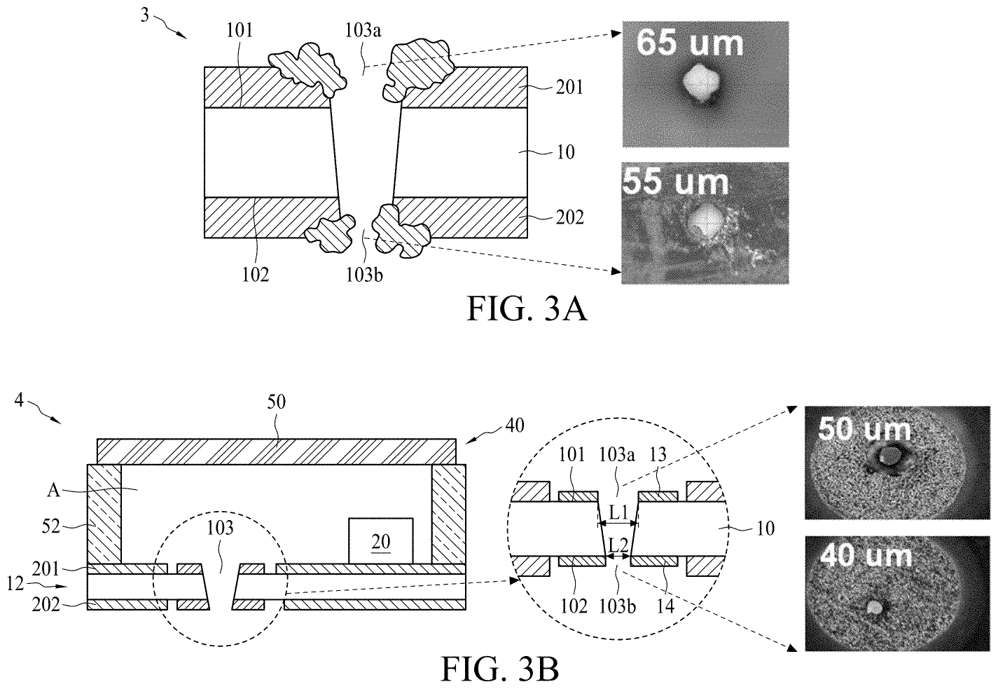

FIG. 3A is a cross-sectional view of a portion of a carrier 12 in accordance with an embodiment of the present disclosure. The through-hole 103 includes an opening 103a proximal to the surface 101 and an opening 103b proximal to the surface 102. In some embodiments, the second aperture of the opening 103b is smaller than the first aperture of the opening 103a. For example, the first aperture of the opening 103a is larger than 65 μm and the second aperture of the opening 103b is larger than 55 μm. The openings 103a and 103b may be blocked due to the thermal carbonization of the surface of the passivation layers 201 and 202 during the laser drilling operation.

FIG. 3B is a cross-sectional view of a device package 4 in accordance with an embodiment of the present disclosure. In some embodiments, the first aperture L1 of the opening 103a ranges from about 45 μm to about 55 μm. In some embodiments, the second aperture L2 of the opening 103b ranges from about 35 μm to about 45 μm. The second aperture L2 of the opening 103b is smaller than the first aperture L1 of the opening 103a. The barrier dam 13 is more thermally conductive and thermally resistant than the passivation layer 201, and thus can alleviate thermal carbonization of the passivation layers 201. By virtue of the barrier dam 13, the first aperture L1 of the opening 103a can be maintained, and the blocking of thermal carbonization of the substrate 10 due to the heat of drilling operation such as the laser drilling operation can be alleviated. The barrier dam 14 is more thermally conductive and thermally resistant than the passivation layer 202, and thus can alleviate thermal carbonization of the passivation layers 202. By virtue of the barrier dam 14, the second aperture L2 of the opening 103b can be maintained, and the blocking of thermal carbonization of the substrate 10 due to the heat of drilling operation such as the laser drilling operation can be alleviated.

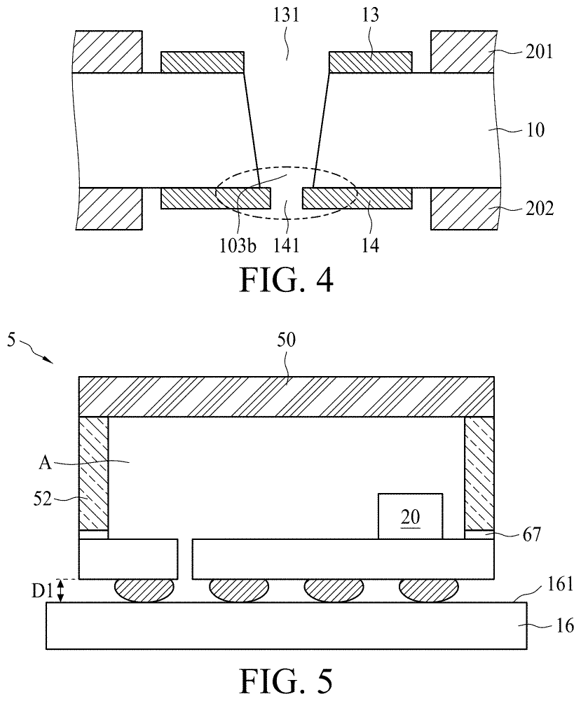

FIG. 4 is a cross-sectional view of a portion of a carrier 12 in accordance with an embodiment of the present disclosure. In some embodiments, the through-hole 103 includes an opening 103a proximal to the surface 101 and an opening 103b proximal to the surface 102. The barrier dam 13 has an opening 131 having a first dimension. The first dimension of the opening 131 of the barrier dam 13 is substantially the same as the first aperture of the opening 103a. The barrier dam 14 has an opening 141 having a second dimension. In some embodiments, the second dimension of the opening 141 is smaller than the second aperture of the opening 103b. The second dimension of the opening 141 of the barrier dam 14 may be about 20 μm to about 50 μm for preventing saw dust from entering the chamber A during the manufacturing operations.

FIG. 5 is a cross-sectional view of a device package 5 in accordance with an embodiment of the present disclosure. The structure of the device package 5 of FIG. 5 is similar to the structure of the device package 1 of FIG. 1 except for the passivation layers 201 and 202 and the barrier dams 13 and 14. The device package 5 comprises a device package 1, a carrier 16 and connection elements 80. The device package 5 does not include the passivation layers 201 and 202 and the barrier dams 13 and 14. The gap D1 between the top surface 161 of the carrier 16 and the surface 102 of the substrate 10 is equal to or less than about 10 The gap D1 being equal to or less than about 10 μm may prevent the saw dust from entering the chamber A during the sawing operations, and thus the yield and reliability of the device package 5 can be improved.

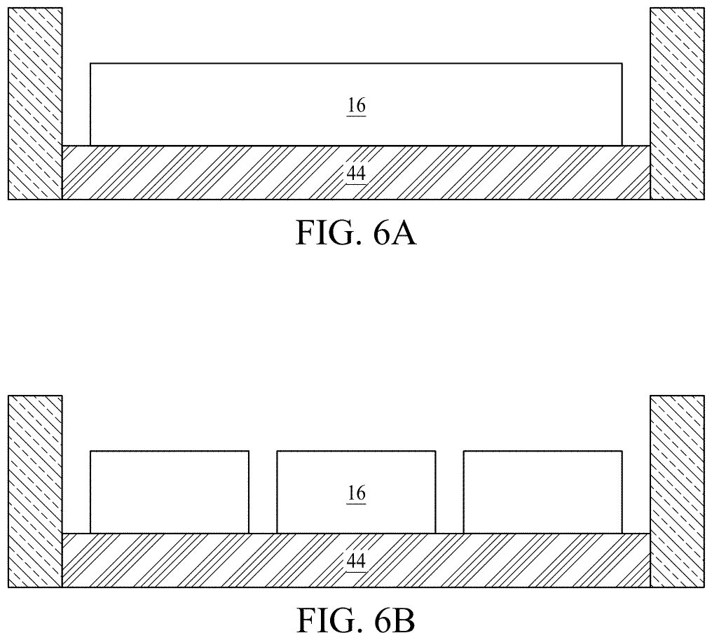

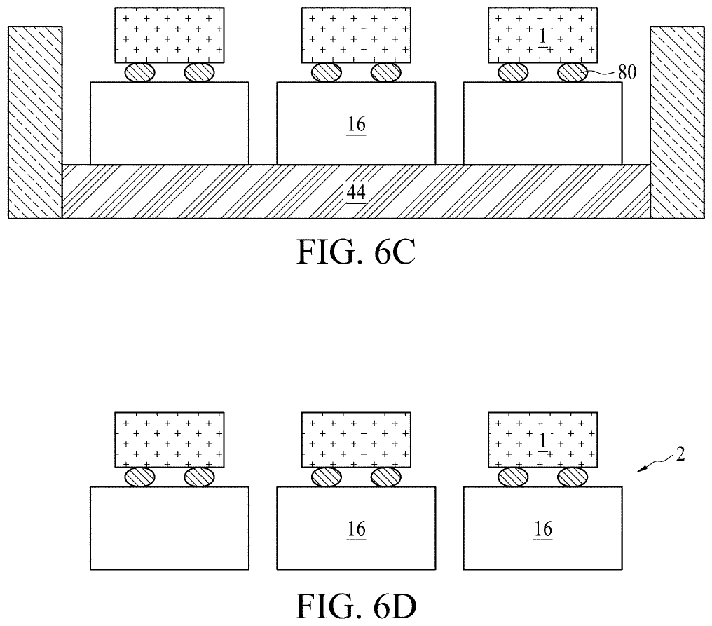

FIGS. 6A-6D illustrate a method of manufacturing a device package 2 in accordance with an embodiment of the present disclosure. Referring to FIG. 6A, a carrier 16 and a tape 44 are provided. The carrier 16 is disposed on the top surface of the tape 44.

Referring to FIG. 6B, the carrier 16 is singulated, for example, by a sawing operation. After the singulation, the plurality of singulated carriers 16 are disposed on the top surface of the tape 44. Referring to FIG. 6C, the plurality of device packages 1 are attached to the carriers 16 through connection elements 80.

Referring to FIG. 6D, the tape 44 is removed. Next, the carriers 16 are separated from the tape 44 and the device packages 2 of FIG. 2 are formed. In some embodiments, the device package 2 comprises a device package 1, a carrier 16, pads 82 (not shown) and connection elements 80.

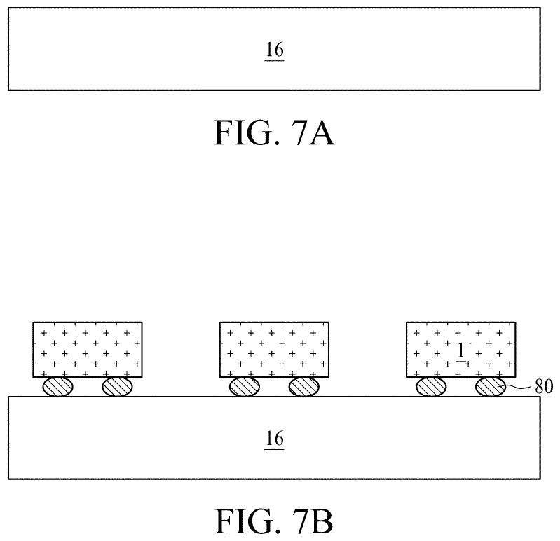

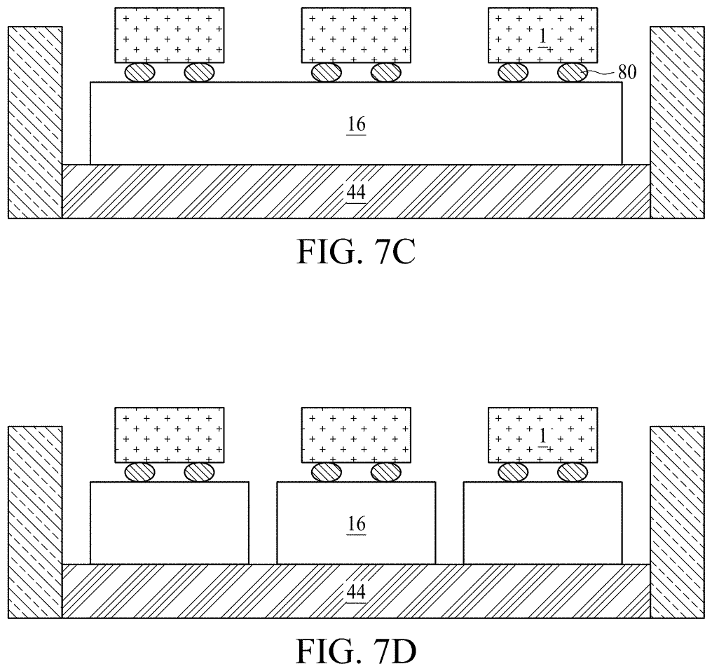

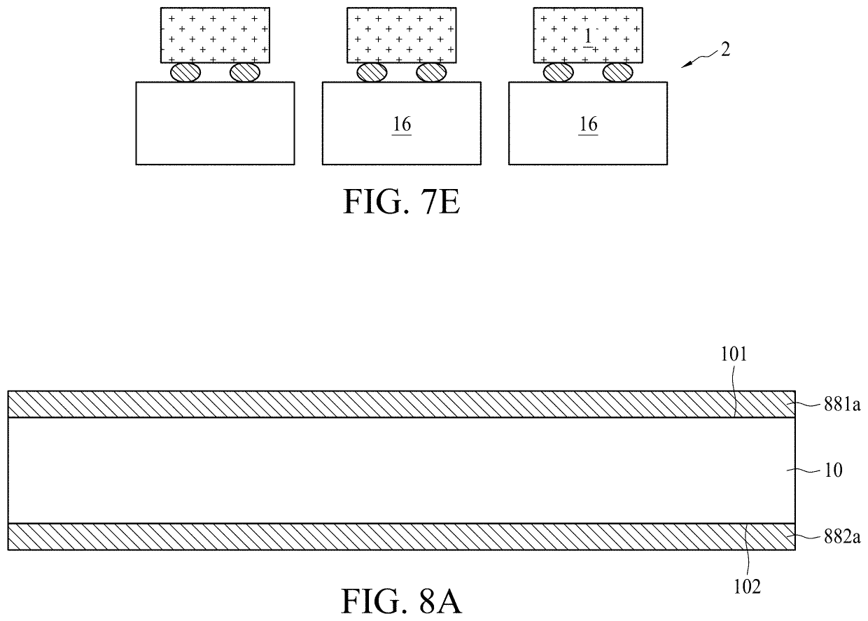

FIGS. 7A-7E illustrate a method of manufacturing a device package 2 in accordance with an embodiment of the present disclosure. Referring to FIG. 7A, a carrier 16 is provided.

Referring to FIG. 7B, a plurality of device packages 1 are disposed on the top surface of the carriers 16. In some embodiments, the device packages 1 are attached to the carriers through pads 82 (not shown) and connection elements 80. The height of the connection elements 80 is such configured that a gap D1 (not shown) being less than about 10 μm.

Referring to FIG. 7C, the carrier 16 is attached to the top surface of a tape 44. Referring to FIG. 7D, the carrier 16 is singulated, for example, by a sawing operation. After the singulation, the plurality of singulated carriers 16 are separated from each other. The sawing operation may result in the saw dust flowing into the chamber A of the device packages 1. The gap D1 (not shown) being less than about 10 μm may prevent the saw dust from entering the chamber A during the sawing operations, and thus the yield and reliability of the device package 2 can be improved. The gap D1 may also prevent the saw dust or water from flowing into the chamber A of the device packages 1 during the subsequent manufacturing operations. The functions and effects of the barrier dams 13 and 14 are similar to those functions discussed above.

Referring to FIG. 7E, the tape 44 is removed. Next, the carriers 16 are separated from the tape 44 and the device packages 2 of FIG. 2 are formed.

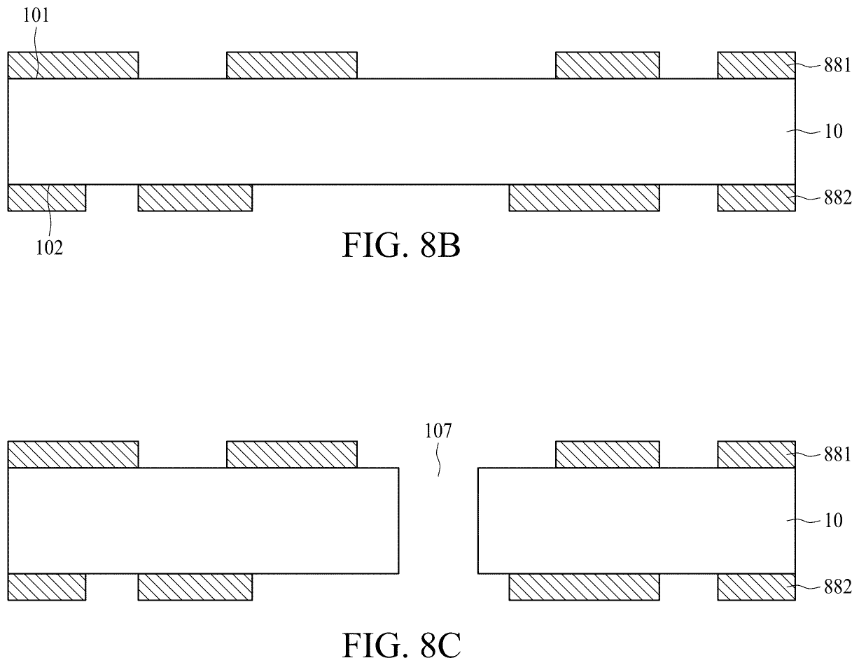

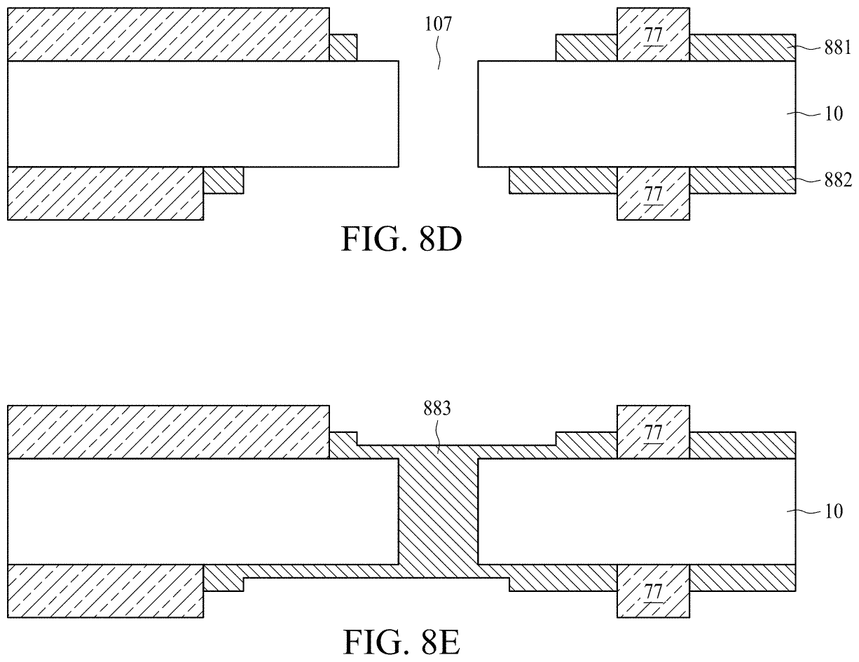

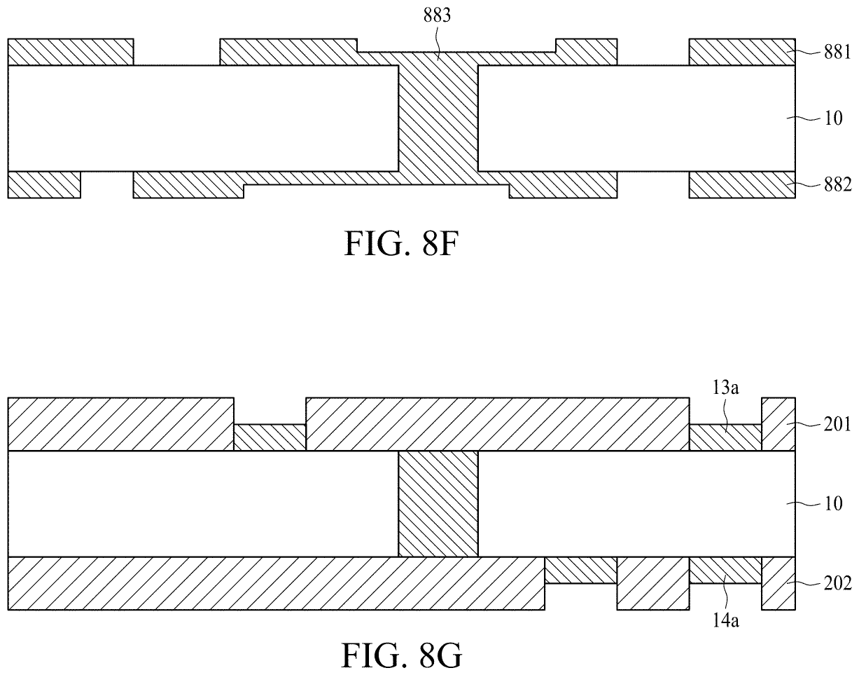

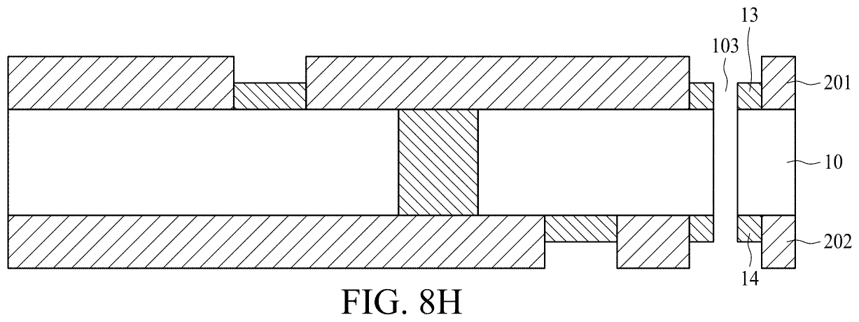

FIGS. 8A-8H illustrate a method of manufacturing a portion of a carrier 12 in accordance with an embodiment of the present disclosure. Referring to FIG. 8A, a substrate 10 is provided. The substrate 10 has a conductive layer 881a on the surface 101 and a conductive layer 882a on the surface 102. In some embodiments, the material of the conductive layers 881a and 882a may individually include metal or alloy such as Cu, copper foil or other suitable materials.

Referring to FIG. 8B, a portion of the conductive layers 881a and 882a is removed by lithography and etching operations. After the removing, the patterned conductive layers 881 and 882 are formed. Referring to FIG. 8C, an opening 107 is formed through the substrate 10. The opening 107 may be formed by laser drilling, etching operations or other suitable operations.

Referring to FIG. 8D, a patterned resist layer 77 such as a photoresist layer is disposed on the patterned conductive layers 881 and 882 and cover a portion of the surface 101 and the surface 102. The patterned resist layer 77 may be formed by coating or another suitable technique.

Referring to FIG. 8E, a patterned conductive layer 883 may be formed by plating or another suitable technique. The patterned conductive layer 883 may fully or partially fill the opening 107. The material of patterned conductive layer 883 may include metal such as Cu, or other suitable materials.

Referring to FIG. 8F, the patterned resist layer 77 is removed by a suitable technique, such as an etching process. After etching, a portion of the surface 101 and a portion of the surface 102 are exposed.

Referring to FIG. 8G, a portion of the patterned conductive layer 883 and a portion of patterned conductive layers 881 and 882 are removed by a suitable technique, such as an etching process. After etching, a patterned passivation layer 201 is formed on the surface 101 and a patterned passivation layer 202 is formed on the surface 102. After forming the patterned passivation layers 201 and 202, the patterned conductive layers 13a and 14a are formed. In some embodiments, the thickness of each of the patterned conductive layers 13a and 14a is less than the thickness of the patterned passivation layers 201 and 202.

Referring to FIG. 8H, a through-hole 103 is formed through the substrate 10. The through-hole 103 may be formed by an etching operation, laser drilling techniques or other suitable operations. The aperture of the through-hole 103 formed by laser drilling operation can be reduced compared to that formed by mechanical drilling operation. The barrier dams 13 and 14 are formed, after forming the through-hole 103. The barrier dam 13 is more thermally conductive and thermally resistant than the passivation layer 201, and thus can alleviate thermal carbonization of the passivation layers 201. By virtue of the barrier dam 13, the first aperture of the opening 103a can be maintained, and the blocking of thermal carbonization of the substrate 10 due to the heat of drilling operation such as the laser drilling operation can be alleviated. The barrier dam 14 is more thermally conductive and thermally resistant than the passivation layer 202, and thus can alleviate thermal carbonization of the passivation layers 202. By virtue of the barrier dam 14, the second aperture of the opening 103b can be maintained, and the blocking of thermal carbonization of the substrate 10 due to the heat of drilling operation such as the laser drilling operation can be alleviated.

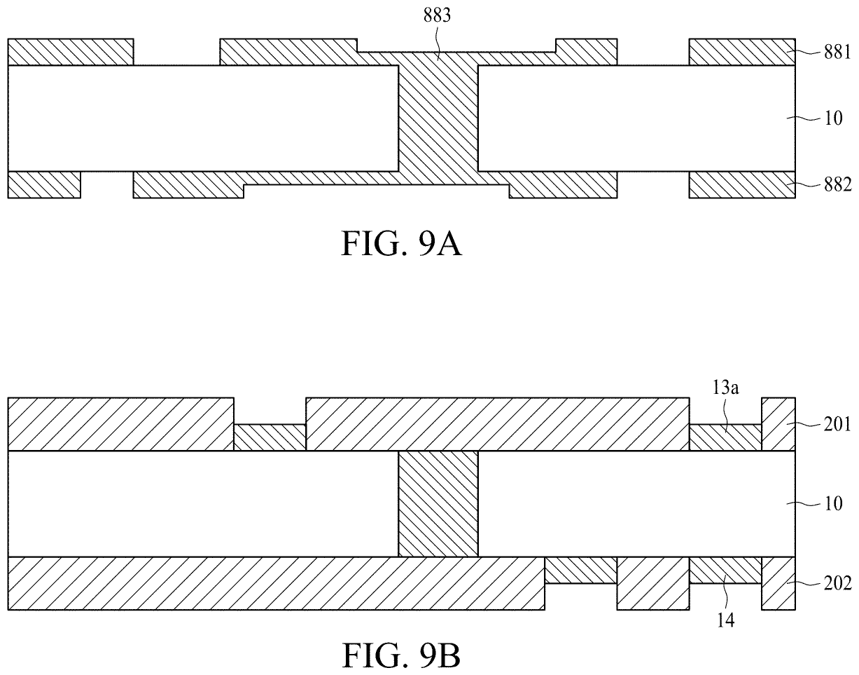

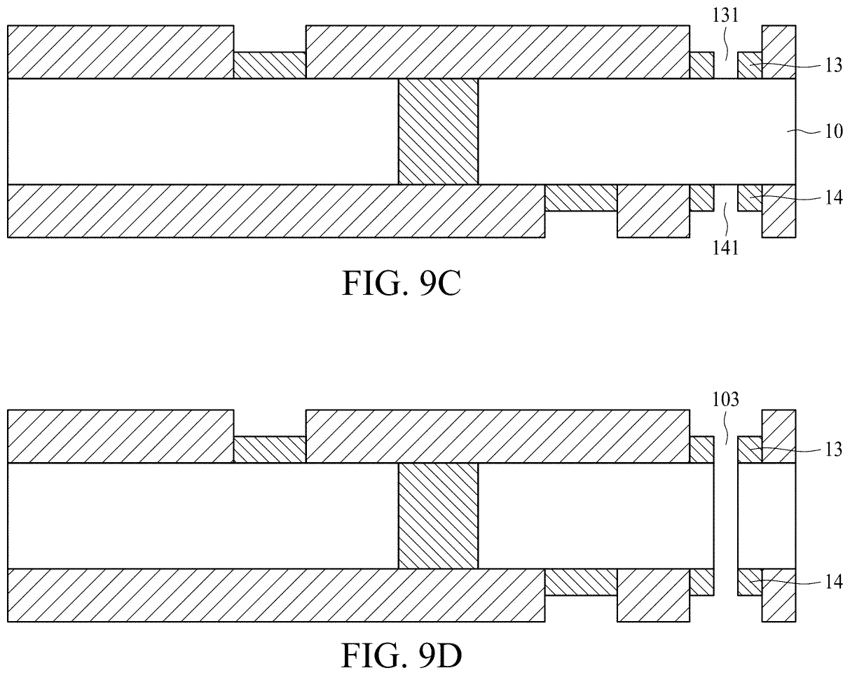

FIGS. 9A-9D illustrate a method of manufacturing a portion of a carrier 12 in accordance with an embodiment of the present disclosure. Referring to FIG. 9A, the similar operations in FIGS. 8A-8E are not described again. In FIG. 9A, the patterned resist layer 77 is removed. A portion of the surface 101 and a portion of the surface 102 are exposed.

Referring to FIG. 9B, a portion of the patterned conductive layer 883 and a portion of patterned conductive layers 881 and 882 are removed by a suitable technique, such as an etching process. After etching, a patterned passivation layer 201 is formed on the surface 101 and a patterned passivation layer 202 is formed on the surface 102. After forming the patterned passivation layers 201 and 202, the patterned conductive layers 13a and 14a are formed.

Referring to FIG. 9C, an opening 131 and an opening 141 are formed in the patterned conductive layers 13a and 13b by a suitable technique, such as an etching process. After forming the opening 131 and opening 141, the barrier dams 13 and 14 are formed, and a portion of the surface 101 and the surface 102 of the substrate 10 is exposed.

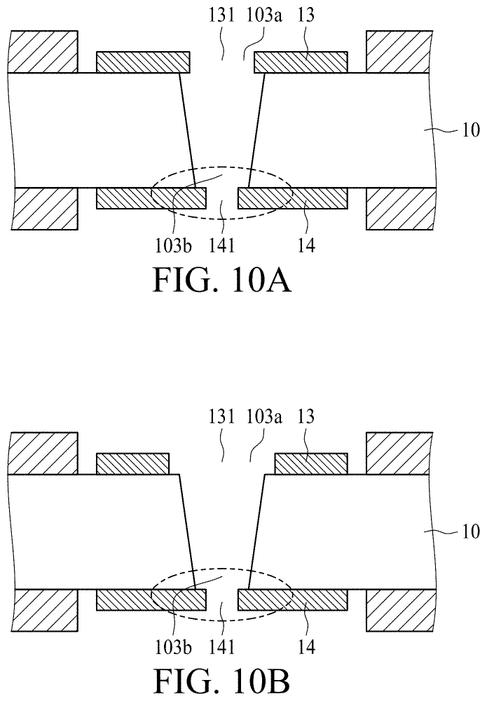

Referring to FIG. 9D, a through-hole 103 is formed by a suitable technique, such as laser drilling operation, etching process or other suitable operations. In some embodiments, the openings 131, 141 and the through-hole 103 are formed independently. For example, the opening 131 and opening 141 are formed in advance, and the opening 131 and opening 141 can be utilized as a mask for patterning the through-hole 103 by etching or laser drilling, for instance. Since the openings 131 and 141 and the through-hole 103 are formed independently, the dimension of the opening 131 may be different from the aperture of the opening 103a and the dimension of the opening 141 may be different from the aperture of the opening 103b as illustrated in FIG. 10A and FIG. 10B by example.

FIGS. 10A and 10B are cross-sectional views of a portion of a carrier 12 in accordance with an embodiment of the present disclosure. Referring to FIG. 10A, the through-hole 103 includes an opening 103a proximal to the surface 101 and an opening 103b proximal to the surface 102. The barrier dam 13 has an opening 131 having a first dimension. The barrier dam 14 has an opening 141 having a second dimension. In some embodiments, the second dimension of the opening 141 is smaller than the second aperture of the opening 103b. The first dimension of the opening 131 of the barrier dam 13 is less than the first aperture of the opening 103a. Referring to FIG. 10B, the first dimension of the opening 131 of the barrier dam 13 is greater than the first aperture of the opening 103a.

In some embodiments of the present disclosure, the device package includes a top barrier dam for maintaining the aperture of the through-hole and eliminating the blocking of thermal carbonization of the substrate due to the heat of the laser drilling operation. The device package includes a small bottom opening of the through-hole or a small opening of the bottom barrier dam for preventing the saw dust from entering the chamber A during the manufacturing operations. The passivation layers may protect the top barrier dam and the bottom barrier dam. In some embodiments of the present disclosure, the gap D1 being less than about 10 μm may prevent the saw dust or water from entering the chamber A during the sawing operations.

As used herein, the terms “approximately” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can encompass a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For another example, a first angle may be approximately the same as a second angle if a difference between the first angle and the second angle is less than or equal to ±10°, such as ±5°, ±4°, ±3°, ±2°, ±1°, ±0.5°, ±0.1°, or ±0.05°.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

1. A device package, comprising:
a first carrier, comprising:
a substrate having a first surface, and a second surface opposite to the first surface, the substrate defining a through-hole extended from the first surface to the second surface, wherein the through-hole includes a first opening proximal to the first surface, and a second opening proximal to the second surface;
a first barrier dam disposed on the first surface and surrounding the first opening of the through-hole; and
a second barrier dam disposed on the second surface and surrounding the second opening of the through-hole;
a lid disposed on the first surface, the lid and the first carrier defining a chamber; and
a chip disposed on the first surface and in the chamber.

2. The device package of claim 1, wherein the first opening of the through-hole has a first aperture, the second opening of the through-hole has a second aperture, and the first aperture is larger than the second aperture.

3. The device package of claim 2, wherein the first barrier dam has an opening having a first dimension, and the first dimension of the opening of the first barrier dam is substantially the same as the first aperture of the first opening.

4. The device package of claim 2, wherein the second barrier dam has an opening having a second dimension.

5. The device package of claim 4, wherein the second dimension of the opening of the second barrier dam is substantially the same as the second aperture of the second opening, and the second aperture of the second opening ranges from about 20 μm to about 50 μm.

6. The device package of claim 4, wherein the second dimension of the opening of the second barrier dam ranges from about 20 μm to about 50 μm.

7. The device package of claim 1, wherein the first barrier dam and the second barrier dam comprise conductive materials.

8. The device package of claim 1, wherein the first carrier further comprises a passivation layer on the second surface of the substrate and partially covering the second barrier dam.

9. The device package of claim 1, further comprising a second carrier, and a plurality of connection elements, wherein the first carrier is electrically connected to the second carrier through the connection element.

10. The device package of claim 9, wherein a gap between the second carrier and the first carrier is less than about 10 μm.

11. A device package, comprising:
a first carrier comprising a first surface, a second surface opposite to the first surface, the first carrier defining a through-hole extended from the first surface to the second surface, wherein the through-hole has a first opening adjacent to the first surface, and a second opening adjacent to the second surface;
a bottom barrier dam disposed on the second surface and surrounding the bottom opening of the through-hole, wherein the bottom barrier dam has an opening, and a dimension of the opening of the bottom barrier dam ranges from about 20 μm to about 50 μm;
a lid on the first surface, the lid and the first carrier defining a chamber; and
a chip disposed on the first surface and in the chamber.

12. The device package of claim 11, wherein an aperture of the first opening is larger than an aperture of the second opening.

13. The device package of claim 12, further comprising a top barrier dam disposed on the first surface and surrounding the first opening of the through-hole, wherein the top barrier dam has an opening, and a dimension of the opening of the top barrier dam is substantially the same as the aperture of the first opening.

14. The device package of claim 13, wherein the bottom barrier dam and the top barrier dam comprise conductive materials.

15. The device package of claim 12, wherein the dimension of the opening of the bottom barrier dam is substantially the same as the aperture of the second opening.

16. The device package of claim 11, further comprising a second carrier, and a plurality of connection elements, wherein the first carrier is electrically connected to the second carrier through the connection element.

17. The device package of claim 16, wherein a gap between the second carrier and the first carrier is less than about 10 μm.

18. The device package of claim 11, wherein the chip comprises an optical chip.

19. An electronic device, comprising:
a first carrier having a top surface; and
a device package disposed on the top surface of the first carrier, the device package comprising:
a second carrier having a first surface and a second surface opposite to the first surface and facing the top surface of the first carrier;
a chip disposed on the first surface; and
a connection element connecting the top surface of the first carrier to the second surface of the second carrier, wherein a gap between the top surface of the first carrier and the second surface of the second carrier is less than about 10 μm.

20. The electronic device of claim 19, further comprising a barrier dam disposed on the second surface of the second carrier, wherein the second carrier includes a through-hole extended from the first surface to the second surface, and the barrier dam surrounds an opening of the through-hole.
